(19) United States
(12) Patent Application Publication
(10) Pub. No.: US 2026/0247628 A1
(43) Pub. Date: Aug. 20, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Jeong Ho YEON, Icheon-si (KR); Min Su KANG, Icheon-si (KR); Nam Kyun PARK, Icheon-si (KR); Jeong Hoon BAE, Icheon-si (KR); Dong Yeol YUN, Icheon-si (KR); Seo Rin CHO, Icheon-si (KR)

(21) Appl. No.: 19/234,718

(22) Filed: Jun. 11, 2025

(30) Foreign Application Priority Data
Feb. 18, 2025 (KR) 10-2025-0021043

(51) Int. Cl. H10B 63/10; H10B 63/00

(52) U.S. Cl. CPC H10B 63/10; H10B 63/84

(57) ABSTRACT

A method of manufacturing a semiconductor device includes forming first row lines that extend in a first direction on a substrate including a cell region and a peripheral circuit region, forming first column lines extending in a second direction crossing the first direction, forming first memory cells respectively positioned between the first row lines and the first column lines in the cell region and the peripheral circuit region, forming a second liner layer that covers the first column lines and the first memory cells, forming a first protective layer on the second liner layer, forming a first trench by etching the first protective layer, the second liner layer, the first column lines, and the first memory cells formed in the peripheral circuit region, forming a first interlayer insulating layer in the first trench, and forming a first contact via that extends through the first interlayer insulating layer.

### CROSS-REFERENCE TO RELATED APPLICATION

This application claims priority under 35 U.S.C. § 119 to Korean Patent Application No. 10-2025-0021043 filed on Feb. 18, 2025, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a method of manufacturing a semiconductor device, the method comprising: forming first row lines that extend in a first direction on a substrate, the substrate including a cell region and a peripheral circuit region; forming first column lines that extend in a second direction crossing the first direction; forming first memory cells respectively positioned between the first row lines and the first column lines in the cell region and the peripheral circuit region; forming a second liner layer that covers the first column lines and the first memory cells; forming a first protective layer on the second liner layer; forming a first trench by etching the first protective layer, the second liner layer, the first column lines, and the first memory cells formed in the peripheral circuit region; forming a first interlayer insulating layer in the first trench; and forming a first contact via that extends through the first interlayer insulating layer.

According to an embodiment of the present disclosure, a method of manufacturing a semiconductor device, the method comprising: forming first row lines that extend in a first direction on a substrate, the substrate including a cell region and a peripheral circuit region; forming first column lines that extend in a second direction crossing the first direction; forming first memory cells respectively positioned between the first row lines and the first column lines; forming a second liner layer that covers the first column lines and the first memory cells; forming a first protective layer on the second liner layer so as to contact the second liner layer; forming a first trench by etching the first protective layer, the second liner layer, the first column lines, and the first memory cells formed in the peripheral circuit region; forming a first interlayer insulating layer in the first trench; and forming a first contact via that extends through the first interlayer insulating layer.

### BRIEF DESCRIPTION OF THE DRAWINGS

FIGS. 1A, 1B, 2A, 2B, 3A, 3B, 4A, 4B, 5A, 5B, 6A, 6B, 7A, 7B, and 7C are drawings illustrating a method of manufacturing a semiconductor device according to an embodiment of the present disclosure.

FIGS. 8A, 8B, 9A, 9B, 10A, 10B, 11A, 11B, and 11C are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided. As used herein, including in the claims, the term ‘or’ in a list of items (e.g., a list introduced by phrases such as ‘at least one of,’ ‘one or more of,’ or ‘one or both of’) is intended to be inclusive unless explicitly stated otherwise. Specifically, the term ‘or’ should be interpreted to cover any individual item in the list, any combination of items in the list, or all items in the list. For example, a phrase such as ‘at least one of A, B, or C’ is intended to encompass A alone, B alone, C alone, any combination of A and B, A and C, or B and C, as well as A, B, and C together. This inclusive interpretation applies unless an explicit indication to the contrary is provided in a particular context. Moreover, a first element “on” a second element indicates that the first element can be “directly on” the second element, or that at least one intervening element can be interposed between the first and second elements.

Hereinafter, some embodiments of the present disclosure are described with reference to the accompanying drawings.

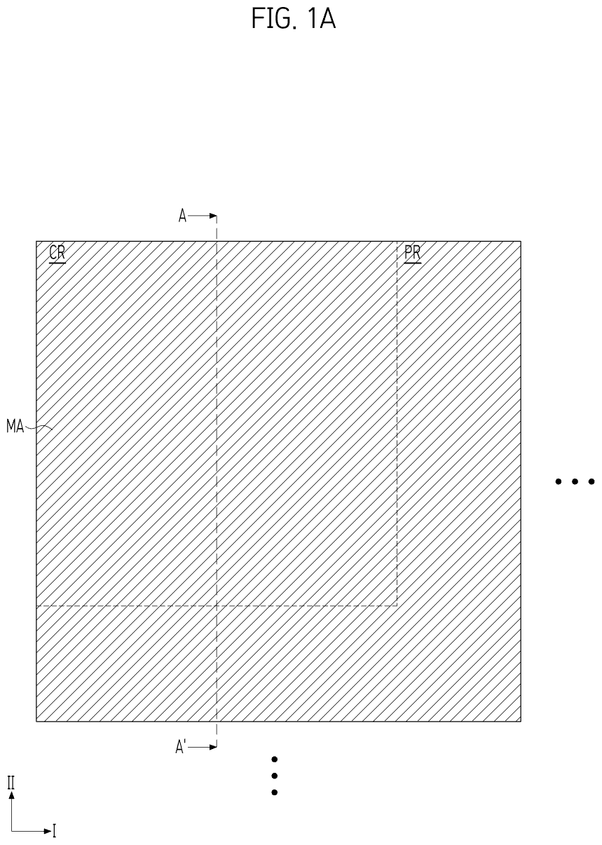

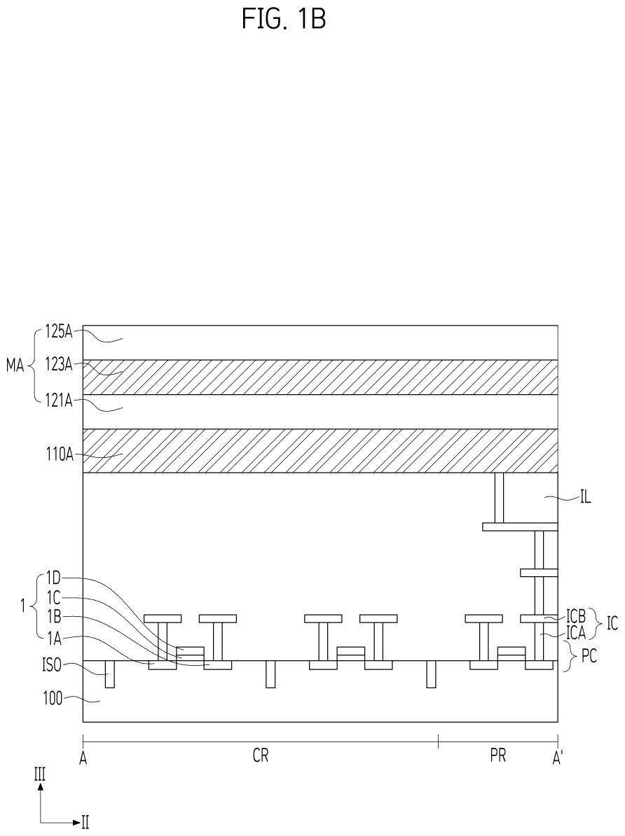

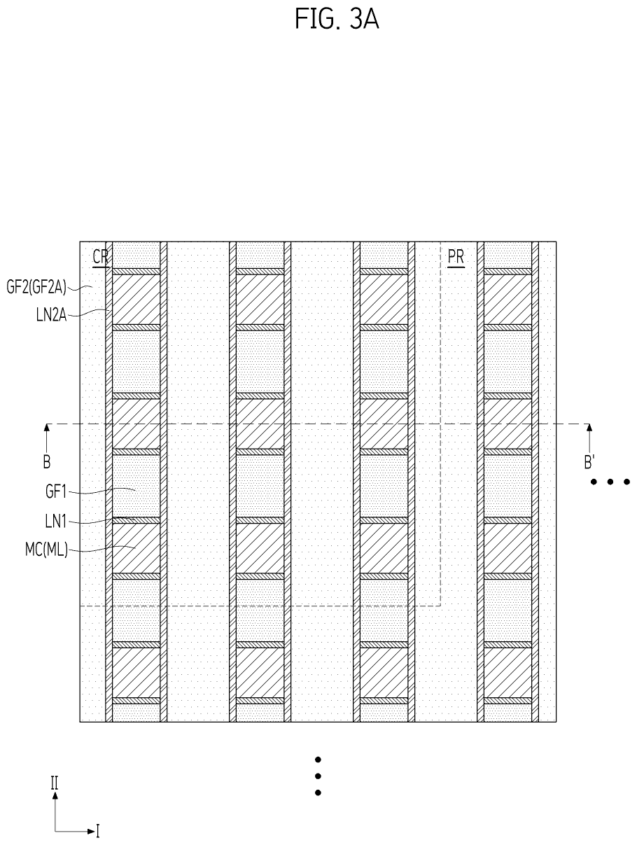

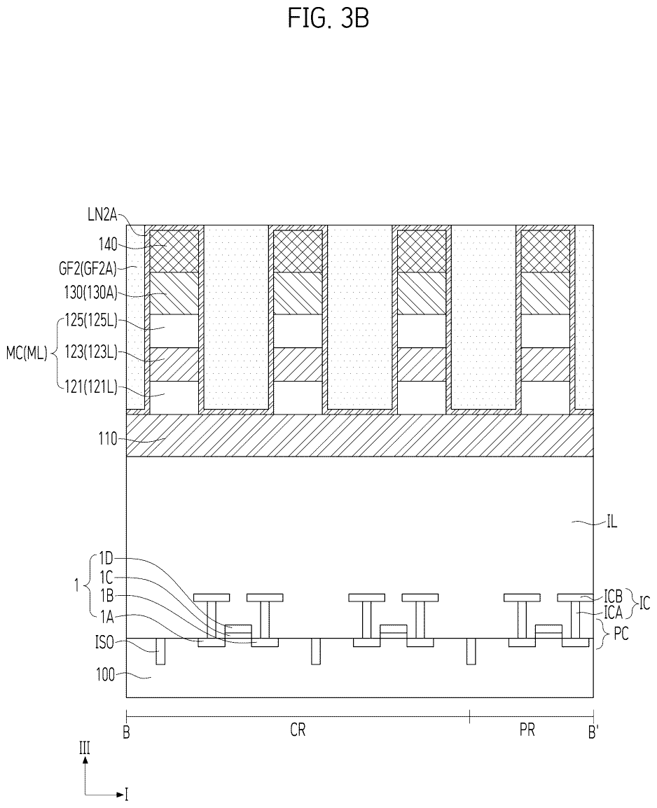

FIGS. 1A, 1B, 2A, 2B, 3A, 3B, 4A, 4B, 5A, 5B, 6A, 6B, 7A, 7B, and 7C are drawings illustrating a method of manufacturing a semiconductor device according to an embodiment of the present disclosure. FIGS. 1A, 2A, 3A, 4A, 5A, 6A, and 7A are plan views, FIGS. 1B, 2B, and 7B are cross-sectional views along the line A-A′ of FIGS. 1A, 2A, and 7A, respectively, and FIGS. 3B, 4B, 5B, 6B, and 7C are cross-sectional views along the line B-B′ of FIGS. 3A, 4A, 5A, 6A, and 7A, respectively.

Referring to FIGS. 1A and 1B, a peripheral circuit PC may be formed on a substrate 100. Here, the substrate 100 may include a cell region CR and a peripheral circuit region PR. The cell region CR may be a region where memory cells are to be formed, and the peripheral circuit region PR may be a region where the peripheral circuit PC is to be formed. However, embodiments of the present disclosure are not limited thereto, and the peripheral circuit PC may be formed in the cell region CR and the peripheral circuit region PR.

The peripheral circuit PC may include a transistor 1 and the like. The transistor 1 may include junctions 1A and 1B, a gate electrode 1D, and a gate insulating layer 1C. Here, the gate insulating layer 1C may be formed between the gate electrode 1D and the substrate 100. An element isolation layer ISO may be formed in the substrate 100. An active region may be defined by the element isolation layer ISO, and the transistor 1 may be formed in the active region.

Subsequently, an interconnection structure IC may be formed on the peripheral circuit PC. The interconnection structure IC may be connected to a contact via to be formed in a subsequent process, and may electrically connect the contact via and the peripheral circuit PC. The interconnection structure IC may be formed in a first interlayer insulating layer IL. Here, the first interlayer insulating layer IL may be positioned on the substrate 100. The interconnection structure IC may include vias ICA and lines ICB.

The interconnection structure IC may be connected to the peripheral circuit PC. For example, at least one of the vias ICA may be connected to the transistor 1. At least one of the vias ICA may interconnect the lines ICB. The lines ICB may interconnect the vias ICA. The interconnection structure IC may include a conductive material such as tungsten. The first interlayer insulating layer IL may include an insulating material such as an oxide.

Subsequently, a first conductive layer 110A may be formed on the substrate 100. Here, the first conductive layer 110A may include a conductive material such as tungsten. Subsequently, a memory layer MA may be formed on the first conductive layer 110A. For example, the memory layer MA may be formed by sequentially stacking a lower electrode layer 121A, a variable resistance layer 123A, and an upper electrode layer 125A on the first conductive layer 110A.

At least one of the lower electrode layer 121A or the upper electrode layer 125A may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), or the like, or may include a combination thereof.

The variable resistance layer 123A may be used as a data storage and a selection element simultaneously. The variable resistance layer 123A may include a resistive material, and may have a characteristic of reversibly changing between different resistance states according to an applied voltage or current. For example, the variable resistance layer 123A may have a low resistance crystalline state by a set operation. In addition, the variable resistance layer 123A may have a high resistance amorphous state by a reset operation. Therefore, the variable resistance layer 123A may store data in the memory cell MC by using a resistance difference according to a phase. The variable resistance layer 123A may include chalcogenide glass, a chalcogenide alloy, or the like.

The variable resistance layer 123A may maintain an amorphous state during a program operation, and may not change to a crystalline state after the program operation. In other words, the phase of the variable resistance layer 123A may not change after the program operation. For example, the variable resistance layer 123A may include a variable resistance material of which a resistance changes without a phase change, and may include a chalcogenide element. The variable resistance layer 123A may include germanium (Ge), antimony (Sb), arsenic (As), silicon (Si), indium (In), tin (Sn), gallium (Ga), or the like, or may include a combination thereof.

The variable resistance layer 123A may include a metal oxide (transition metal oxide), or may include a metal oxide such as a perovskite material. Therefore, data may be stored in the memory cell MC as an electrical path is generated or disappeared in the variable resistance layer 123A.

The variable resistance layer 123A may have an MTJ structure, and may include a magnetization fix layer, a magnetization free layer, and a tunnel barrier layer interposed therebetween. For example, the magnetization fix layer and the magnetization free layer may include a magnetic material, and the tunnel barrier layer may include an oxide including a least one of magnesium (Mg), aluminum (Al), zinc (Zn), or titanium (Ti). Here, a magnetization direction of the magnetization free layer may be changed by spin torque of electrons in an applied current. Therefore, data may be stored in the memory cell MC according to a change in the magnetization direction of the magnetization free layer with respect to the magnetization direction of the magnetization fix layer.

The variable resistance layer 123A may have a metal insulator metal (MIM) structure including a metal oxide. In this case, data may be stored in the memory cell MC by using a resistance change of the metal oxide that occurs by applying a short electric pulse.

For reference, the memory layer MA may further include a switching layer (not shown) and an intermediate electrode layer (not shown). Here, the switching layer may be formed between the lower electrode layer 121A and the intermediate electrode layer, and the intermediate electrode layer may be formed between the switching layer and the variable resistance layer 123A. In this case, the lower electrode layer 121A, the switching layer, and the intermediate electrode layer may configure a selection element. The selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the switching layer may include a chalcogenide material. In addition, the intermediate electrode layer, the variable resistance layer 123A, and the upper electrode layer 125A may configure a memory element. The memory element and the selection element may share the intermediate electrode layer.

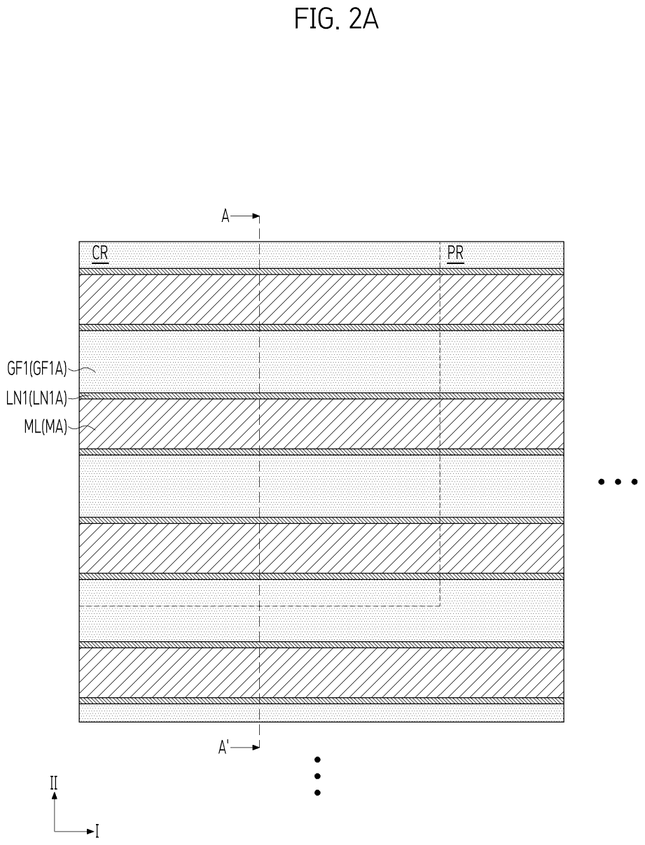

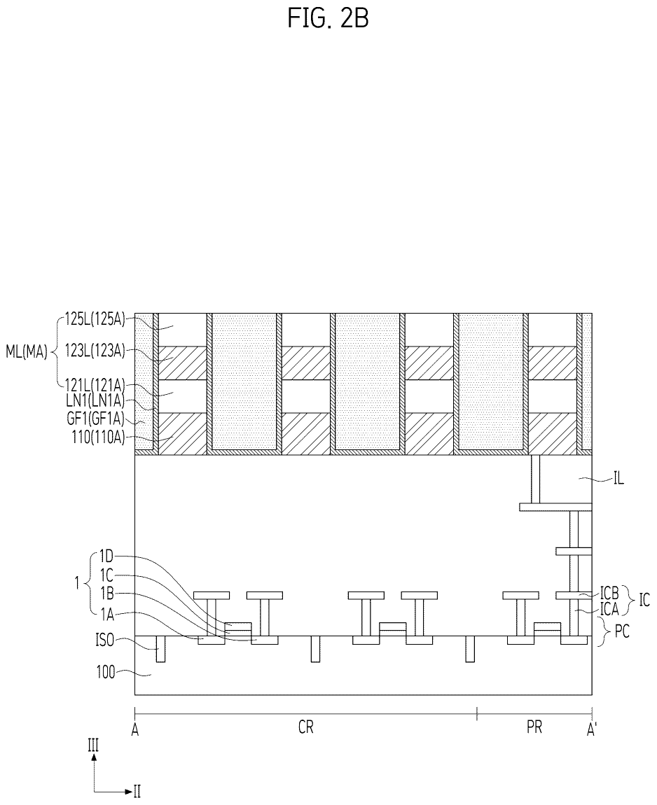

Referring to FIGS. 2A and 2B, memory lines ML extending in a first direction I may be formed. For example, the memory lines ML including upper electrode lines 125L, variable resistance lines 123L, and lower electrode lines 121L may be formed by sequentially etching the upper electrode layer 125A, the variable resistance layer 123A, and the lower electrode layer 121A. For reference, each of the memory lines ML may further include an intermediate electrode line and a switching line.

Row lines 110 extending in the first direction I may be formed by etching the first conductive layer 110A. In other words, the row lines 110 extending in the first direction I may be formed on the substrate 100 including the cell region CR and the peripheral circuit region PR. Here, the row lines 110 may be used as a word line or a bit line.

Subsequently, a first liner layer LN1A may be formed on the memory lines ML. For example, the first liner layer LN1A may be formed to cover the memory lines ML and the row lines 110. Here, the first liner layer LN1A may be formed along a profile of the memory lines ML and the row lines 110. Specifically, the first liner layer LN1A may be formed to substantially entirely cover top surfaces and opposing sidewalls of the memory lines ML and opposing sidewalls of the row lines 110. For example, two opposing sidewalls of each of the memory lines ML and the row lines 110 are adjacent to each other in the second direction II. The first liner layer LN1A may include an insulating material such as a nitride.

Subsequently, a first gap fill layer GF1A may be formed on the first liner layer LN1A. For example, the first gap fill layer GF1A may be formed to fill a region between the memory lines ML. The first gap fill layer GF1A may include an insulating material such as an oxide.

Subsequently, the first gap fill layer GF1A may be planarized so that an upper surface of the memory lines ML is exposed. In this process, the first gap fill layer GF1A may be separated into first gap fill patterns GF1. In addition, the first liner layer LN1A may be separated into first liner patterns LN1.

Referring to FIGS. 3A and 3B, a second conductive layer 130A may be formed on the memory lines ML. For example, the second conductive layer 130A may be formed on the memory lines ML, the first gap fill patterns GF1, and the first liner patterns LN1. Here, the second conductive layer 130A may include a conductive material such as tungsten.

Subsequently, additional protective layers 140 may be formed on the memory lines ML. For example, the additional protective layers 140 may be formed on the second conductive layer 130A. Here, the additional protective layers 140 may extend in a second direction II crossing the first direction I. The additional protective layers 140 may include an insulating material such as a nitride.

Subsequently, column lines 130 extending in the second direction II may be formed by etching the second conductive layer 130A. For example, the column lines 130 extending in the second direction II may be formed by etching the second conductive layer 130A, using the additional protective layers 140 as an etching barrier.

Subsequently, memory cells MC may be formed by etching the memory lines ML. For example, the memory cells MC may be formed by etching the memory lines ML, using the additional protective layers 140 as an etching barrier. The memory cells MC including the upper electrode patterns 125, the variable resistance patterns 123, and lower electrode patterns 121 may be formed by etching upper the electrode lines 125L, the variable resistance lines 123L, and the lower electrode lines 121L. For reference, each of the memory cells MC may further include a switching pattern and an intermediate electrode pattern.

Subsequently, a second liner layer LN2A covering the column lines 130 and the memory cells MC may be formed. For example, the second liner layer LN2A covering the additional protective layers 140, the column lines 130, and the memory cells MC may be formed. Specifically, the second line layer LN2A may be formed to substantially entirely cover top surfaces and opposing sidewalls of the additional protective layers 140, opposing sidewalls of the column lines 130, and opposing sidewalls of the memory cells MC. For example, two opposing sidewalls of each of the additional protective layers 140, the column lines 130, and the memory cells MC are adjacent to each other in the first direction I.

Subsequently, second gap fill patterns GF2 may be formed to fill a region between the memory cells MC. First, a second gap fill layer GF2A may be formed on the second liner layer LN2A. Subsequently, the second gap fill layer GF2A may be planarized so that an upper surface of the second liner layer LN2A is exposed. Here, the upper surface of the second liner layer LN2A may be included in an upper portion of the second liner layer LN2A contacting the additional protective layers 140, and may indicate a region that is first exposed when the second gap fill layer GF2A is planarized. In this process, the second gap fill layer GF2A may be separated into second gap fill patterns GF2. Here, the second gap fill layer GF2A may be filled with an insulating material such as an oxide.

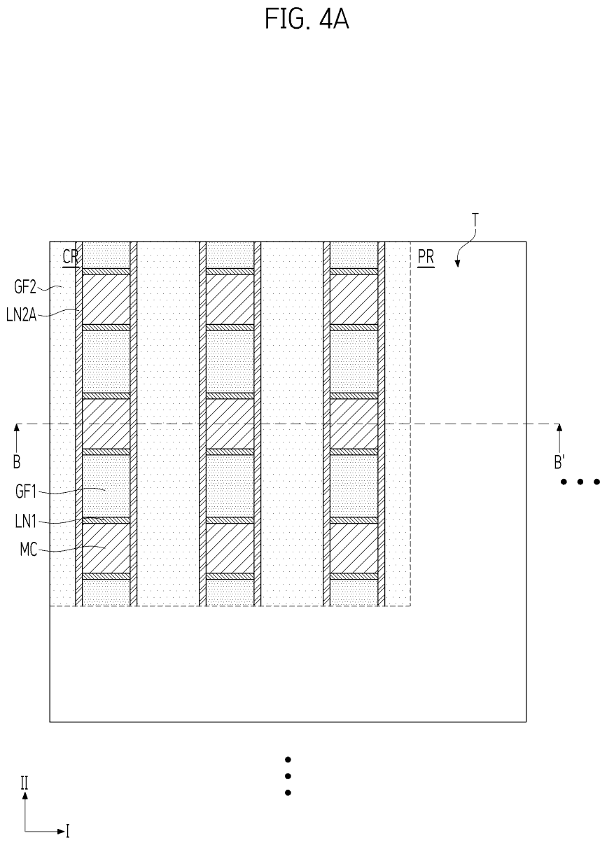

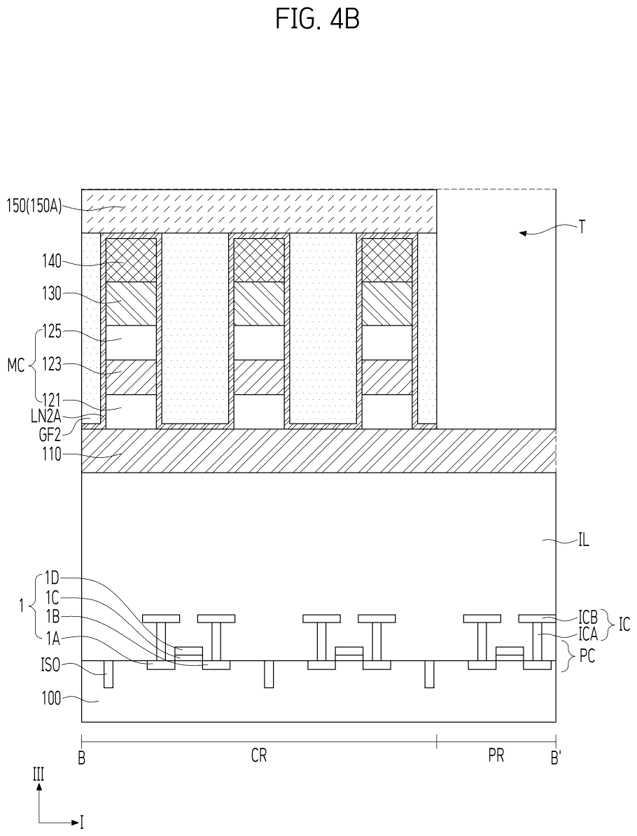

Referring to FIGS. 4A and 4B, a first protective layer 150A may be formed on the memory cells MC of the cell region CR and the peripheral circuit region PR. For example, the first protective layer 150A may be formed on the second liner layer LN2A. Here, the first protective layer 150A may be formed to contact the second liner layer LN2A. Here, the first protective layer 150A may include an insulating material such as a nitride.

Subsequently, a trench T may be formed in the peripheral circuit region PR. For example, the trench T may be formed by etching the first protective layer 150A, the second liner layer LN2A, the column lines 130, and the memory cells MC formed in the peripheral circuit region PR. In other words, the trench T may be formed by etching a portion of the first protective layer 150A, a portion of the second liner layer LN2A, some of the additional protective layers 140, portions of the column lines 130, and some of the memory cells MC formed in the peripheral circuit region PR. In this case, the row lines 110 of the peripheral circuit region PR may be exposed. Here, a portion of the first protective layer 150A remaining in the cell region CR may be defined as a first protective pattern 150.

A plasma process may be used when forming the trench T in the peripheral circuit region PR. In this case, a radical may be generated, and when the radical diffuses into the memory cells MC, the memory cells MC may be damaged. According to an embodiment of the present disclosure, the first protective layer 150A may be formed to contact the second liner layer LN2A. In this case, because the first protective layer 150A may prevent or reduce the movement of the radical, damage to the memory cells MC may be prevented or reduced.

In addition, according to an embodiment of the present disclosure, the second liner layer LN2A and the first liner patterns LN1 together surround the memory cells MC2. In this case, even though a portion of the radical passes through the first protective layer 150A, because the second liner layer LN2A and the first liner patterns LN1 may additionally prevent or reduce movement of the radical, damage to the memory cells MC may be prevented or reduced.

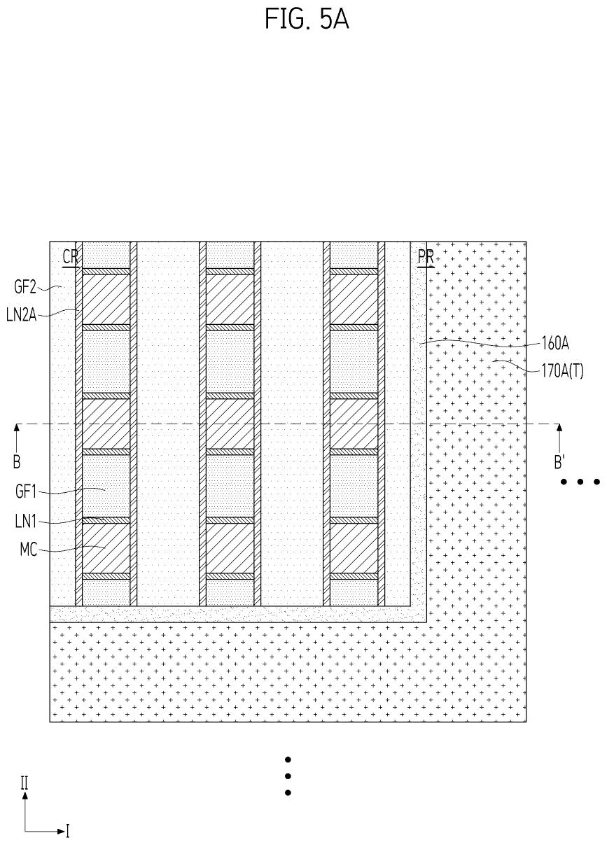

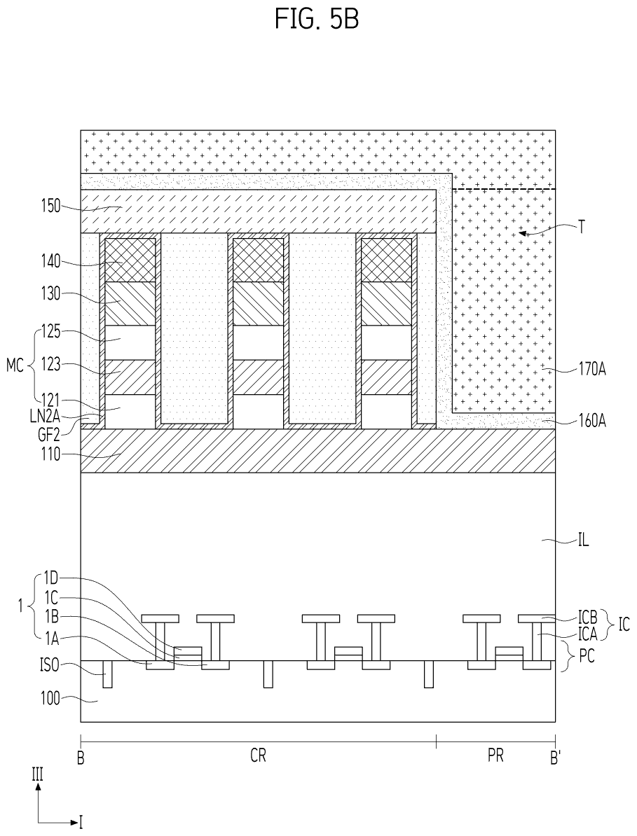

Referring to FIGS. 5A and 5B, a second protective layer 160A may be formed in the trench T. For example, the second protective layer 160A may be formed along the first protective pattern 150 and in the trench T to extend from the cell region CR to the peripheral circuit region PR. In this case, the second protective layer 160A may cover a sidewall of the memory cells MC. Here, the second protective layer 160A may include an insulating material such as a nitride.

For reference, although FIG. 5B shows a boundary surface between the first protective pattern 150 and the second protective layer 160A, embodiments of the present disclosure are not limited thereto. In some embodiments, the first protective pattern 150 and the second protective layer 160A may include substantially the same material, and thus the boundary surface between the first protective pattern 150 and the second protective layer 160A may not exist. In other words, the first protective pattern 150 and the second protective layer 160A may form a single integrated body without having a boundary surface therebetween.

Subsequently, a second interlayer insulating layer 170A may be formed in the trench T. For example, the second interlayer insulating layer 170A may be formed on the second protective layer 160A. Here, the second interlayer insulating layer 170A may include an insulating material such as an oxide.

An external material such as oxygen may diffuse into the memory cells MC through the trench T in a process of forming the second interlayer insulating layer 170A. In this case, the memory cells MC may be damaged. According to an embodiment of the present disclosure, before forming the second interlayer insulating layer 170A, the second protective layer 160A may be formed in the trench T. In this case, because diffusion of an external material such as oxygen into the memory cells MC may be prevented or reduced, damage to the memory cells MC may be prevented or reduced.

In addition, according to an embodiment of the present disclosure, the first protective layer 150A may be formed to contact the second liner layer LN2A. In this case, the first protective layer 150A may prevent or reduce diffusion of an external material such as oxygen into the memory cells MC in the process of forming the second interlayer insulating layer 170A. Therefore, damage to the memory cells MC may be prevented or reduced.

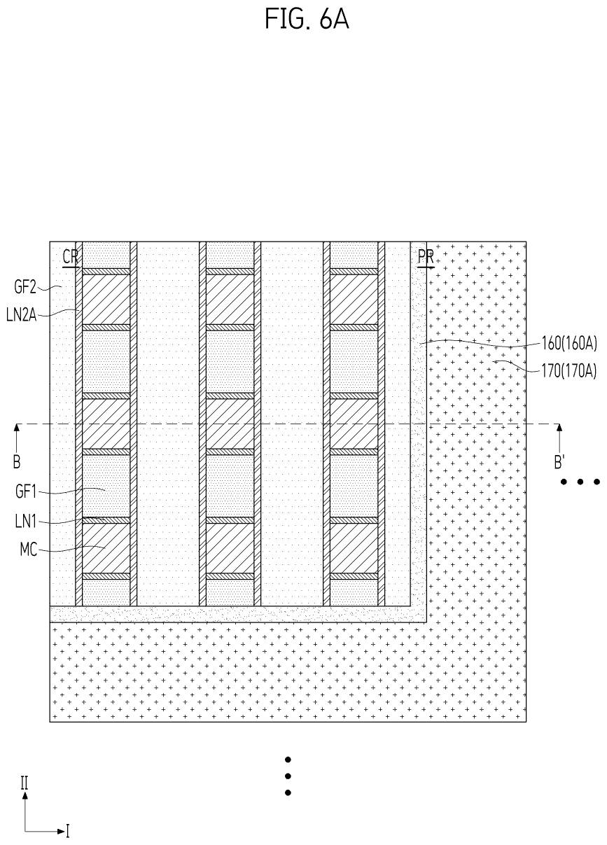

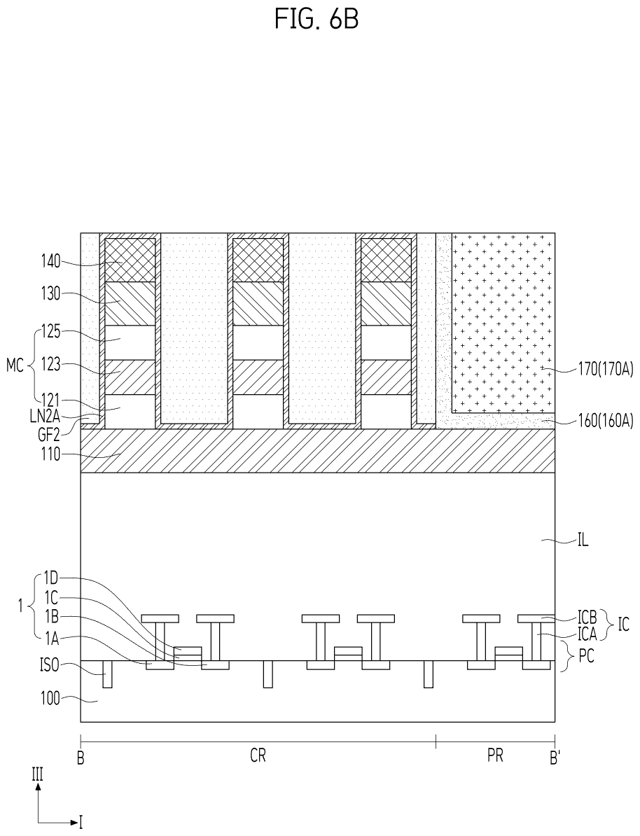

Referring to FIGS. 6A and 6B, the second interlayer insulating layer 170A, the second protective layer 160A, and the first protective pattern 150 may be etched, using the second liner layer LN2A formed in the cell region CR as an etching stop layer. For example, after the second liner layer LN2A of FIG. 3B in the peripheral circuit region PR has been etched, a remaining portion of the second liner layer LN2A in the cell region CR may be used as an etching stop layer. In this case, an upper surface of the second liner layer LN2A may be exposed. Because the second liner layer LN2A and the first liner patterns LN1 together surround the memory cells MC, the memory cells MC may be substantially prevented from being damaged in a process of etching the second interlayer insulating layer 170A, the second protective layer 160A, and the first protective pattern 150. Here, a portion of the second interlayer insulating layer 170A remaining in the peripheral circuit region PR may be defined as a second interlayer insulating pattern 170, and a portion of the second protective layer 160A remaining in the peripheral circuit region PR may be defined as a second protective pattern 160.

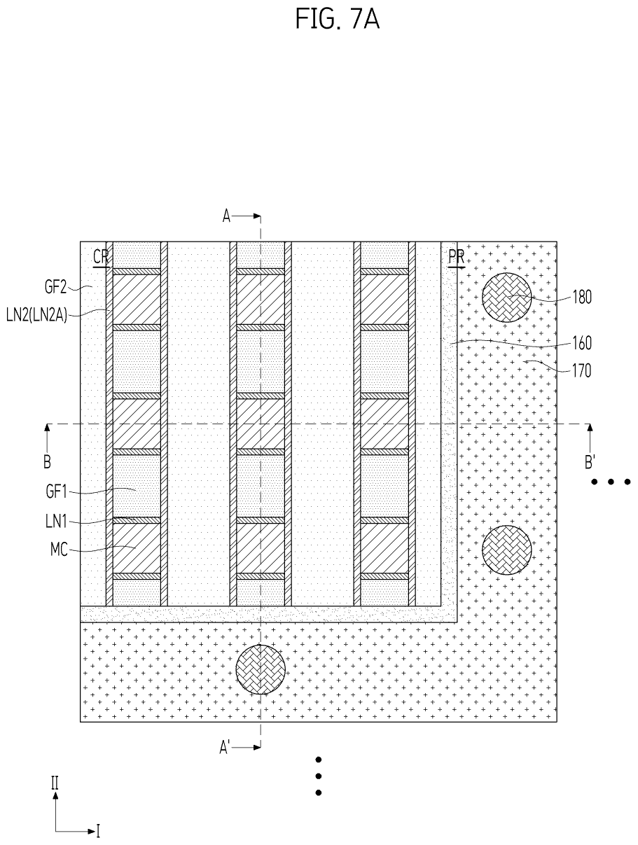

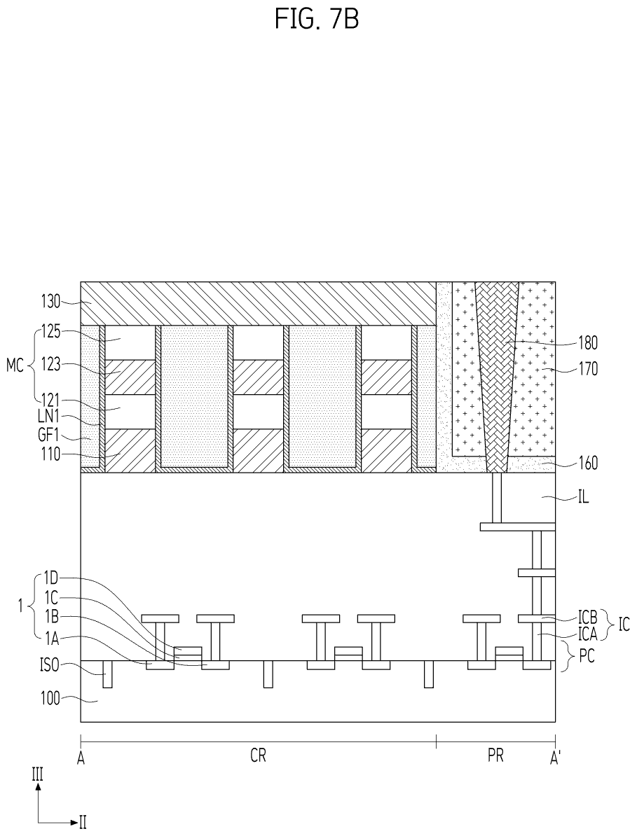

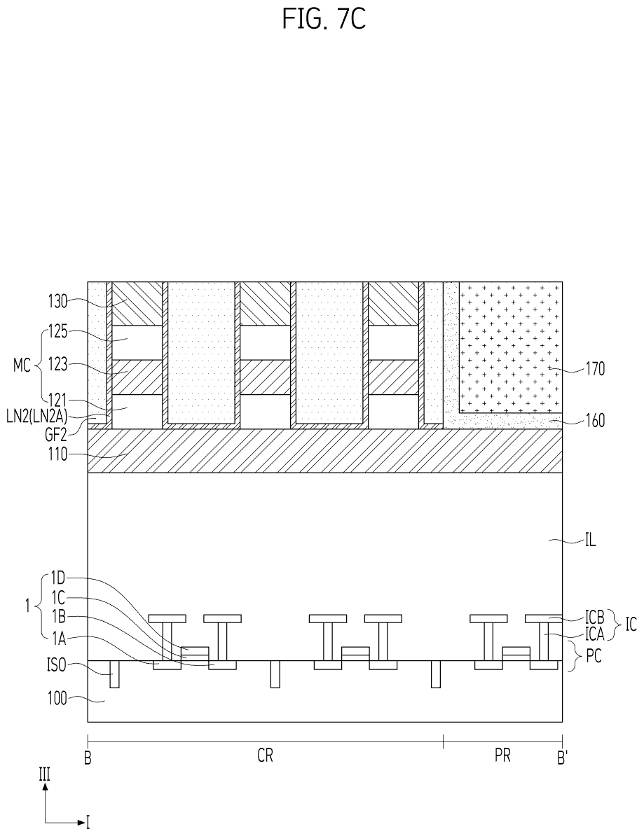

Referring to FIGS. 7A to 7C, additional protective layers 140 may be etched so that the column lines 130 are exposed. In this process, the second liner layer LN2A may be separated into the second liner patterns LN2. According to an embodiment of the present disclosure, the second liner layer LN2A may be etched after forming the trench T of the peripheral circuit region PR or after etching the second protective layer 160A and the first protective pattern 150. In other words, in the method of manufacturing the semiconductor device, by etching the second liner layer LN2A in a relatively late step of the method, the second liner layer LN2A may protect the memory cells MC until the relatively late step.

Subsequently, a contact via 180 extending through the second interlayer insulating pattern 170 may be formed. For example, the contact via 180 extending through the second interlayer insulating pattern 170 and the second protective pattern 160 may be formed. Here, the contact via 180 may be connected to the interconnection structure IC. Therefore, the contact via 180 may be electrically connected to the peripheral circuit PC through the interconnection structure IC. In other words, the interconnection structure IC may be connected to the contact via 180 and the peripheral circuit PC to electrically connect the contact via 180 and the peripheral circuit PC. The contact via 180 may include a conductive material such as tungsten.

According to the manufacturing method described above, the second liner layer LN2A may be formed to cover the memory cells MC. In addition, the first protective layer 150A may be formed to contact the second liner layer LN2A. In this case, even though a plasma process is used when forming the trench T in the peripheral circuit region PR, the memory cells MC may be substantially prevented from being damaged. Therefore, the memory cells MC may be protected.

In addition, the second protective layer 160A may be formed from the cell region CR to the peripheral circuit region PR along the first protective pattern 150. In addition, the second liner layer LN2A may be separated into the second liner patterns LN2 at a relatively late step in the method of manufacturing the semiconductor device. In this case, an external material such as oxygen may be prevented from diffusing into the memory cells MC in the process of forming the second interlayer insulating layer 170A in the trench T of the peripheral circuit region PR. Therefore, the memory cells MC may be protected. In other words, according to an embodiment of the present disclosure, a portion of the second liner layer LN2A in the cell region CR remains unetched while the trench T is formed and subsequently the second interlayer insulating layer 170A is formed in the trench T, thereby protecting the memory cells in the cell region CR.

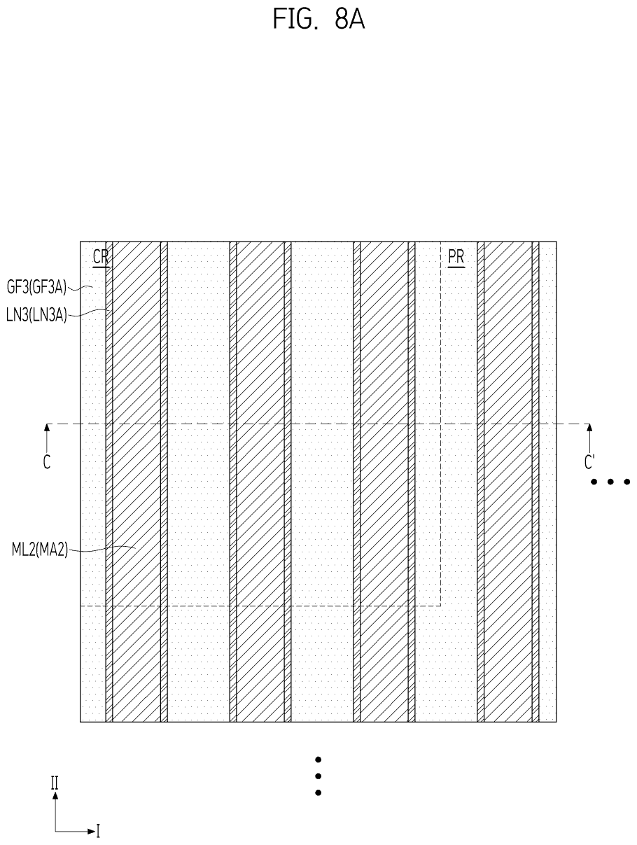

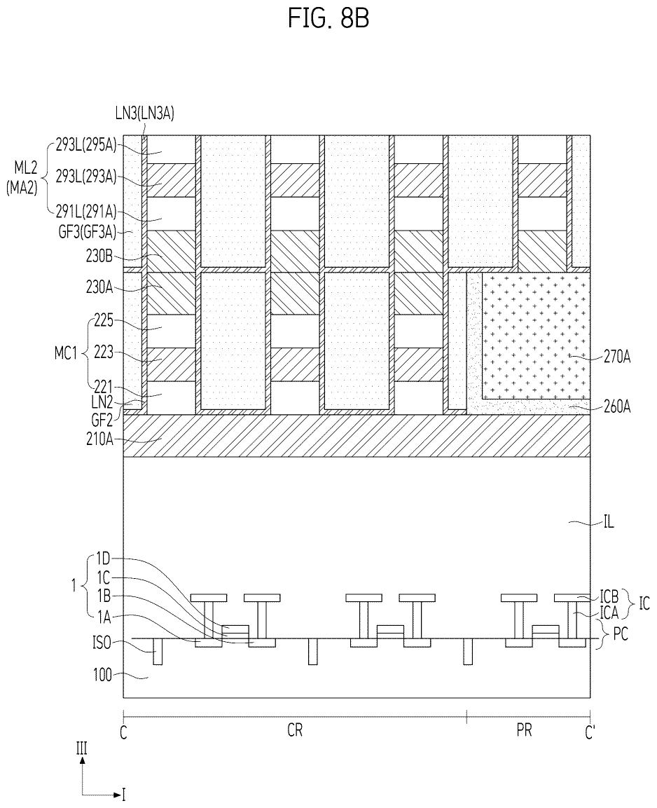

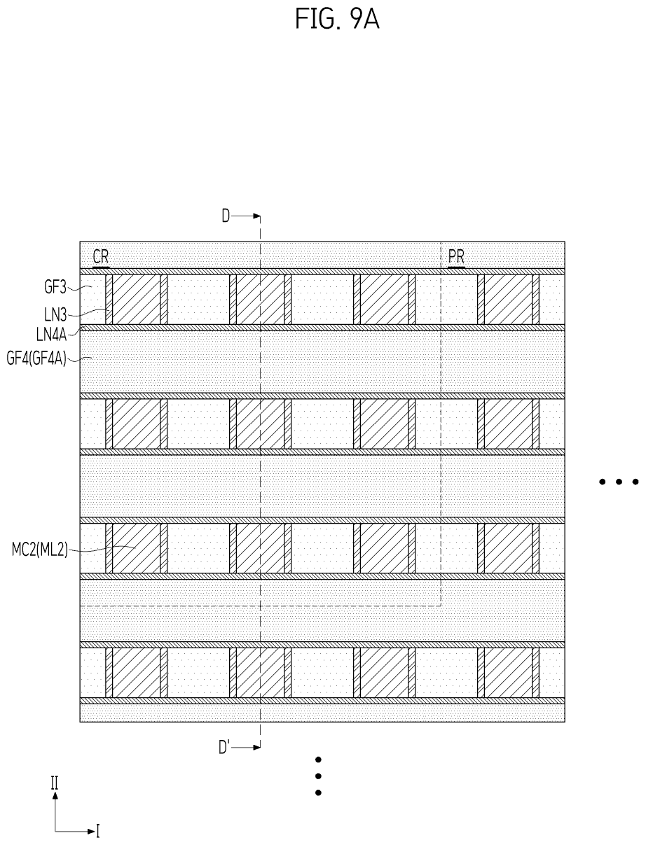

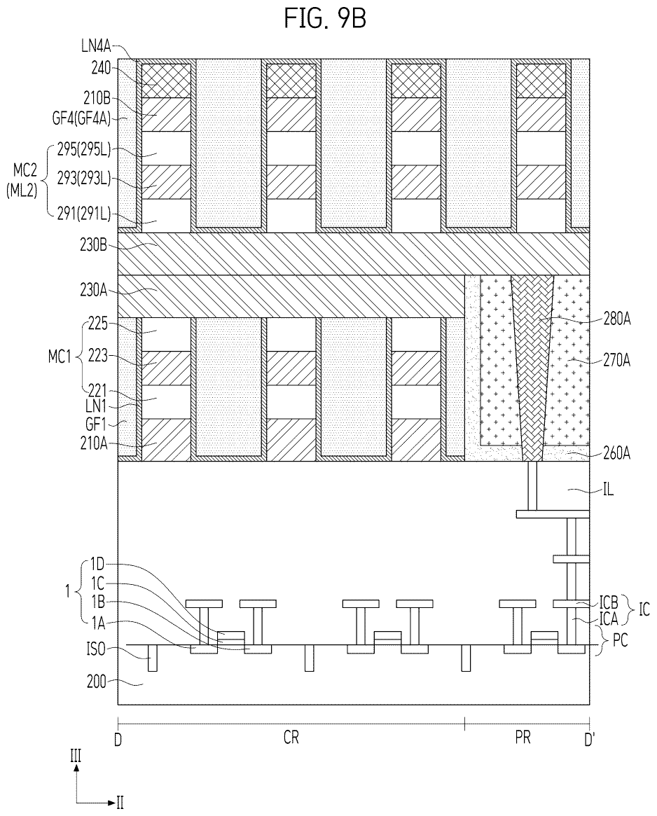

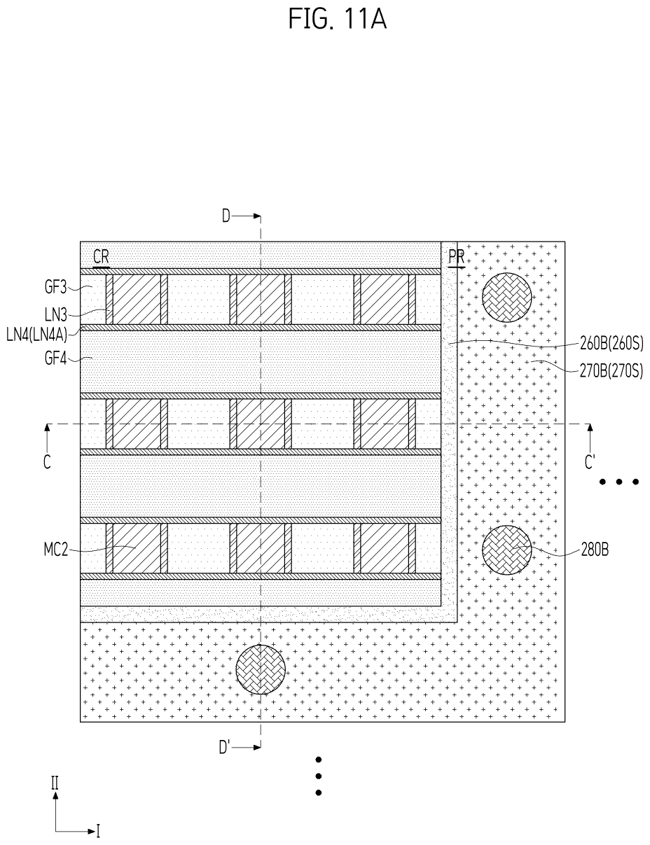

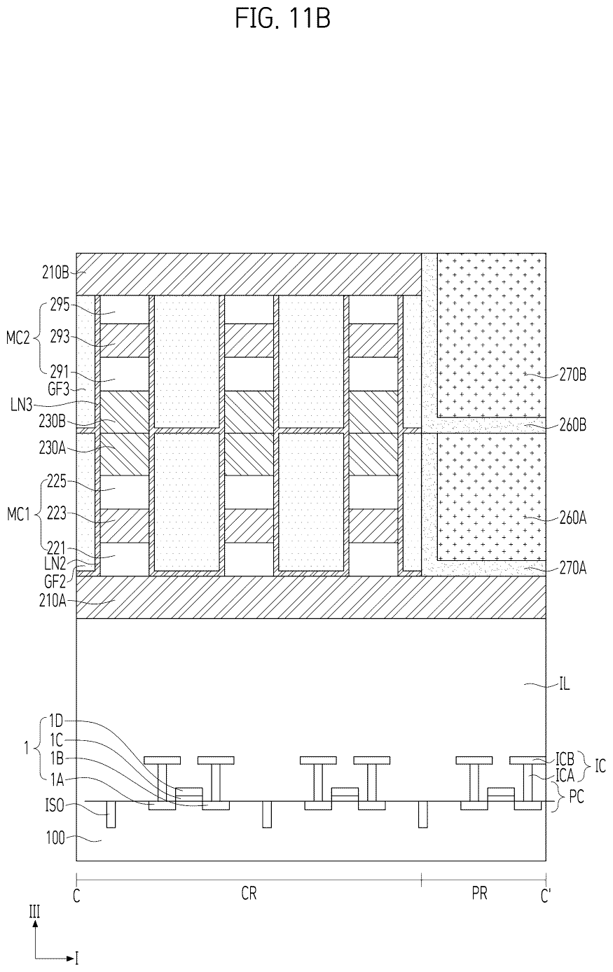

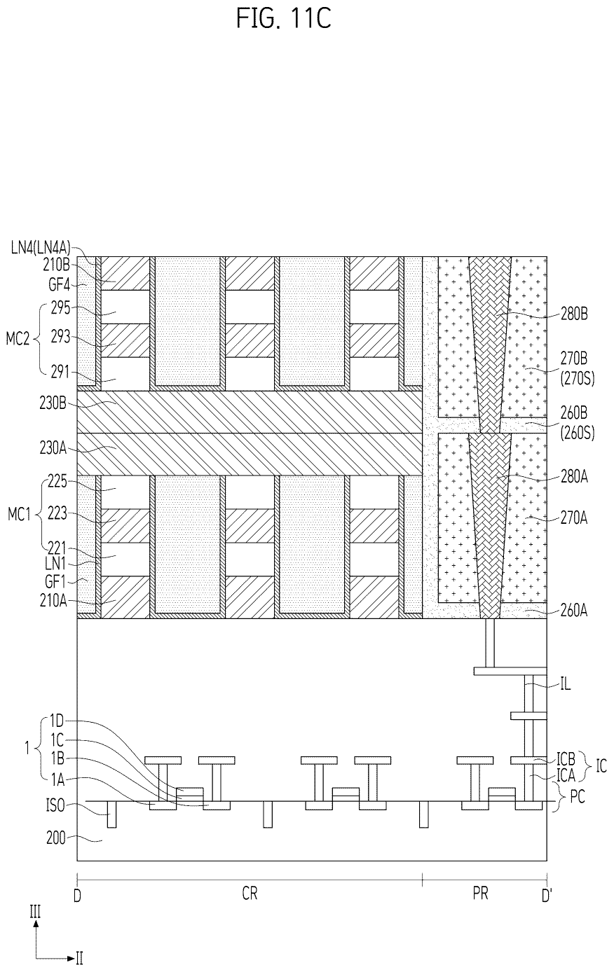

FIGS. 8A, 8B, 9A, 9B, 10A, 10B, 11A, 11B, and 11C are drawings illustrating a method of manufacturing a semiconductor device according to an embodiment of the present disclosure. FIGS. 8A, 9A, 10A, and 11A are plan views, FIGS. 8B and 11B are C-C′ cross-sectional views of FIGS. 8A and 11A, respectively, and FIGS. 9B, 10B, and 11C are D-D′ cross-sectional views of FIGS. 9A, 10A, and 11A, respectively. Hereinafter, a content that overlaps the content described above is omitted.

Referring to FIGS. 8A and 8B, a peripheral circuit PC and an interconnection structure IC may be formed on a substrate 200 including a cell region CR and a peripheral circuit region PR. Here, the interconnection structure IC may be formed in a first interlayer insulating layer IL1.

Subsequently, first row lines 210A extending in a first direction I may be formed on the substrate 200. For example, the first row lines 210A may be formed on the interconnection structure IC. Subsequently, first column lines 230A extending in a second direction II crossing the first direction I may be formed. Subsequently, first memory cells MC1 respectively positioned between the first row lines 210A and the first column lines 230A may be formed in the cell region CR and the peripheral circuit region PR. Here, each of the first memory cells MC1 may include a first lower electrode pattern 221, a first variable resistance pattern 223, and a first upper electrode pattern 225.

Second liner patterns LN2 may be formed on sidewalls adjacent in the first direction I of the first memory cells MC1 in the cell region CR. In addition, second gap fill patterns GF2 may be formed between the first memory cells MC1 adjacent in the first direction I in the cell region CR. Although not shown in this drawing, first liner patterns may be formed on the sidewalls adjacent in the second direction II of the first memory cells MC1 in the cell region CR. In addition, first gap fill patterns may be formed between the first memory cells MC1 adjacent in the second direction II in the cell region CR.

A second protective pattern 260A and a second interlayer insulating pattern 270A may be formed in the peripheral circuit region PR. Here, the second interlayer insulating pattern 270A may be formed on the second protective pattern 260A. In addition, a first contact via extending through the second interlayer insulating pattern 270A and the second protective pattern 260A may be formed in the peripheral circuit region PR.

For reference, a process of forming the peripheral circuit PC, the interconnection structure IC, the first interlayer insulating layer IL, the first row lines 210A, the first column lines 230A, the first memory cells MC1, the first liner patterns, the second liner patterns LN2, the first gap fill patterns, the second gap fill patterns GF2, the second protective pattern 260A, the second interlayer insulating layer 270A, and the first contact via may correspond to a process of forming the peripheral circuit PC, the interconnection structure IC, the first interlayer insulating layer IL, the row lines 110, the column lines 130, the memory cells MC, the first liner patterns LN1, the second liner patterns LN2, the first gap fill patterns GF1, the second gap fill patterns GF2, the second protective pattern 160, the second interlayer insulating layer 170, and the contact via 180 of FIGS. 1A to 7C.

For example, a second liner layer covering the first memory cells MC1 and the first additional protective layers may be formed. Subsequently, a first protective layer may be formed on the second liner layer. Subsequently, a first trench may be formed in the peripheral circuit region PR. Subsequently, a second protective layer may be formed in the first trench. Subsequently, a second interlayer insulating layer 270A may be formed in the first trench. Subsequently, the second interlayer insulating layer 270A, the second protective layer, the first protective layer, the second liner layer, and the first additional protective layers may be removed so that the first column lines 230A are exposed. Subsequently, a first contact via extending through the second interlayer insulating layer 270A may be formed.

Subsequently, a third conductive layer may be formed on the first column lines 230A. Subsequently, a second memory layer MA2 may be formed on the third conductive layer. The second memory layer MA2 may include a second lower electrode layer 291A, a second variable resistance layer 293A, and a second upper electrode layer 295A. The third conductive layer may include a conductive material such as tungsten.

Subsequently, second memory lines ML2 extending in the second direction II may be formed by etching the second memory layer MA2. Here, each of the second memory lines may include a second lower electrode line 291L, a second variable resistance line 293L, and a second upper electrode line 295L.

Subsequently, second column lines 230B extending in the second direction II may be formed on the first column lines 230A. For example, the second column lines 230B extending in the second direction II may be formed by etching the third conductive layer. For reference, the second column lines 230B may be used as common column lines together with the first column lines 230A.

Subsequently, a third liner layer LN3A covering the second memory lines ML2 and the second column lines 230B may be formed. Specifically, the third liner layer LN3A may be formed to substantially entirely cover top surfaces and opposing sidewalls of the second memory lines ML2 and opposing sidewalls of the second column lines 230B. For example, two opposing sidewalls of each of the second memory lines ML2 and the second column lines 230B are adjacent to each other in the first direction I. Subsequently, a third gap fill layer GF3A may be formed to fill a region between the second memory lines ML2. Here, the third liner layer LN3A may include an insulating material such as a nitride, and the third gap fill layer GF3A may include an insulating material such as an oxide.

Subsequently, the third gap fill layer GF3A and the third liner layer LN3A may be etched so that the second memory lines ML2 are exposed. In this process, the third gap fill layer GF3A may be separated into third gap fill patterns GF3. In addition, the third liner layer LN3A may be separated into third liner patterns LN3.

Referring to FIGS. 9A and 9B, a fourth conductive layer may be formed on the second memory lines ML2. Here, the fourth conductive layer may include a conductive material such as tungsten. Subsequently, second additional protective layers 240 may be formed on the fourth conductive layer. Each of the second additional protective layers 240 may extend in the first direction I. Here, the second additional protective layers 240 may correspond to the additional protective layers 140 of FIGS. 4A and 4B, and may include an insulating material such as a nitride. Subsequently, second row lines 210B extending in the first direction I may be formed by etching the fourth conductive layer.

Subsequently, second memory cells MC2 respectively positioned between the second column lines 230B and the second row lines 210B may be formed in the cell region CR and the peripheral circuit region PR. For example, the second memory cells MC2 may be formed by etching the second memory lines ML2, using the second additional protective layers 240 as an etching barrier. Here, each of the second memory cells MC2 may include a second lower electrode pattern 291, a second variable resistance pattern 293, and a second upper electrode pattern 295.

Subsequently, a fourth liner layer LN4A covering the second additional protective layers 240, the second row lines 210B, and the second memory cells MC2 may be formed. Specifically, the fourth liner layer LN4A may be formed to substantially entirely cover top surfaces of the second additional protective layers 240, opposing sidewalls of the second row lines 210B, opposing sidewalls of the second memory cells MC2. For example, two opposing sidewalls of each of the second additional protective layers 240, the second row lines 210B, and the second memory cells MC2 are adjacent to each other in the second direction II. Subsequently, a fourth gap fill layer GF4A may be formed on the fourth liner layer LN4A. Here, the fourth liner layer LN4A may include an insulating material such as a nitride, and the fourth gap fill layer GF4A may include an insulating material such as an oxide.

Subsequently, the fourth gap fill layer GF4A may be planarized so that an upper surface of the fourth liner layer LN4A is exposed. In this process, the fourth gap fill layer GF4A may be separated into fourth gap fill patterns GF4.

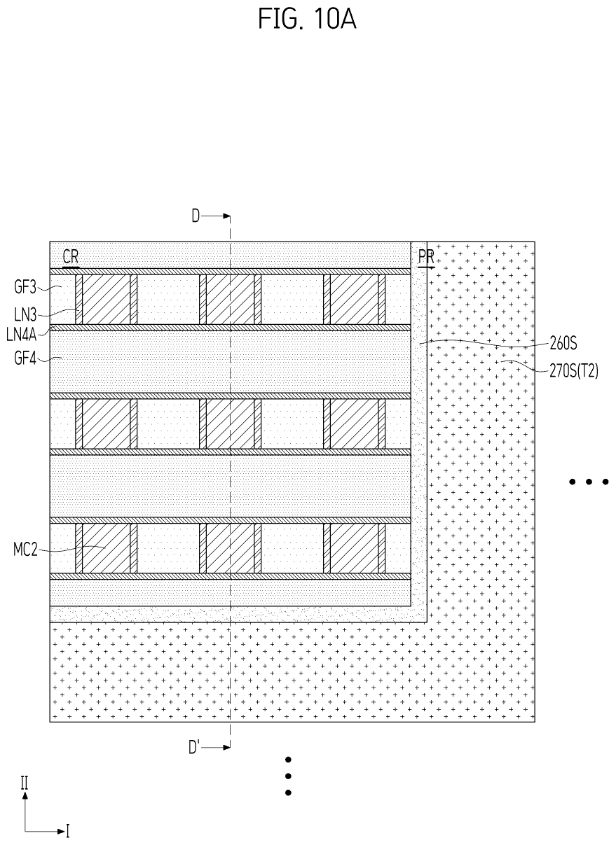

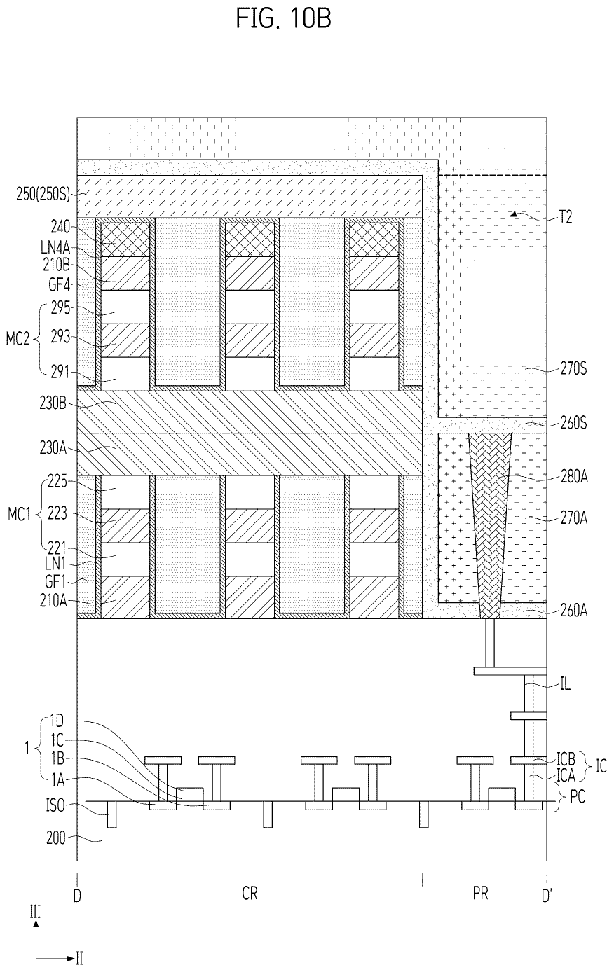

Referring to FIGS. 10A and 10B, a third protective layer 250S may be formed on the fourth liner layer LN4A. Here, the third protective layer 250S may be formed to contact the fourth liner layer LN4A. The third protective layer 250S may correspond to the first protective layer 150 of FIGS. 4A and 4B, and may include an insulating material such as a nitride.

Subsequently, a second trench T2 may be formed in the peripheral circuit region PR. For example, the second trench T2 may be formed by etching the third protective layer 250S, the fourth liner layer LN4A, the second additional protective layers 240, the second row lines 210B, the second memory cells MC2, and the second column lines 230B formed in the peripheral circuit region PR. The second trench T2 may expose the first contact via 280A. Here, the third protective layer 250S remaining in the cell region CR may be defined as a third protective pattern 250. The third protective layer 250S and the fourth liner layer LN4A may prevent or reduce damage to the second memory cells MC2 in a process of forming the second trench T2.

Subsequently, a fourth protective layer 260S may be formed in the second trench T2. For example, the fourth protective layer 260S may be formed along the third protective pattern 250 and in the second trench T2 to extend from the cell region CR to the peripheral circuit region PR. Here, the fourth protective layer 260S may correspond to the second protective layer 260A of FIGS. 5A and 5B. The fourth protective layer 260S may include an insulating material such as a nitride.

Subsequently, a third interlayer insulating layer 270S may be formed in the second trench T2. For example, the third interlayer insulating layer 270S may be formed on the fourth protective layer 260S. Here, the third interlayer insulating layer 270S may correspond to the second interlayer insulating layer 170A of FIGS. 5A and 5B, and may include an insulating material such as an oxide. The fourth protective layer 260S and the fourth liner layer LN4A may prevent or reduce damage to the second memory cells MC2 in a process of forming the third interlayer insulating layer 270S.

Referring to FIGS. 11A and 11B, the third interlayer insulating layer 270S, the fourth protective layer 260S, and the third protective pattern 250 may be etched, using the fourth liner layer LN4A formed in the cell region CR as an etching stop layer. In this process, the fourth liner layer LN4A may protect the second memory cells MC2. Here, the third interlayer insulating layer 270S remaining in the peripheral circuit region PR may be defined as a third interlayer insulating pattern 270B, and the fourth protective layer 260S remaining in the peripheral circuit region PR may be defined as a fourth protective pattern 260B.

Subsequently, the second additional protective layers 240 may be etched so that the second row lines 210B are exposed. In this process, the fourth liner layer LN4A may be separated into fourth liner patterns LN4. According to an embodiment of the present disclosure, by performing a process of etching the fourth liner layer LN4A in a latter step of the process, the fourth liner layer LN4A may protect the second memory cells MC2 until the latter step.

Subsequently, a second contact via 280B extending through the third interlayer insulating pattern 270B may be formed. For example, the second contact via 280B extending through the third interlayer insulating pattern 270B and the fourth protective pattern 260B may be formed. The second contact via 280B may be connected to the first contact via 280A. Therefore, the second contact via 280B may be electrically connected to the peripheral circuit PC through the first contact via 280A and the interconnection structure IC.

According to the manufacturing method described above, the fourth liner layer LN4A, the second additional protective layers 240, the third protective layer 250S, and the fourth protective layer 260S may be formed. Through this, the second memory cells MC2 may be substantially prevented from being damaged in a process of manufacturing the semiconductor device.

In addition, the second memory cells MC2 may be formed by stacking the second memory cells MC2 on the first memory cells MC1. The first memory cells MC1 and the second memory cells MC2 may share the first column lines 230A and the second column lines 230B.

Although some embodiments of the present disclosure have been described with reference to the accompanying drawings, various embodiments of the present disclosure are not limited to the above-described embodiments. Various forms of substitution, modification, and change of the embodiments will be possible by those skilled in the art to which the present disclosure belongs, and these also belong to embodiments of the present disclosure.

What is claimed is:

1. A method of manufacturing a semiconductor device, the method comprising:
forming first row lines that extend in a first direction on a substrate, the substrate including a cell region and a peripheral circuit region;
forming first column lines that extend in a second direction crossing the first direction;
forming first memory cells respectively positioned between the first row lines and the first column lines in the cell region and the peripheral circuit region;
forming a second liner layer that covers the first column lines and the first memory cells;
forming a first protective layer on the second liner layer;
forming a first trench by etching the first protective layer, the second liner layer, the first column lines, and the first memory cells formed in the peripheral circuit region;
forming a first interlayer insulating layer in the first trench; and
forming a first contact via that extends through the first interlayer insulating layer.

2. The method of claim 1, wherein a remaining portion of the first protective layer in the cell region after etching the first protective layer in the peripheral circuit region is a first protective pattern, the method further comprising:
forming a second protective layer along the first protective pattern and in the first trench to extend from the cell region to the peripheral circuit region; and
forming the first interlayer insulating layer on the second protective layer.

3. The method of claim 2, wherein the first protective layer contacts the second liner layer.

4. The method of claim 2, wherein at least one of the first protective layer or the second protective layer includes a nitride.

5. The method of claim 1, further comprising:
forming first memory lines that extend in the first direction;
forming first additional protective layers on the first memory lines; and
etching the first memory lines to form the first memory cells, using the first additional protective layers as an etching barrier.

6. The method of claim 5, wherein the second liner layer covers the first additional protective layers, the first column lines, and the first memory cells.

7. The method of claim 5, wherein, a remaining portion of the first protective layer in the cell region after etching the first protective layer in the peripheral circuit region is a first protective pattern, the method further comprising:
forming a second protective layer along the first protective pattern and in the first trench;
etching the first interlayer insulating layer, the second protective layer, and the first protective pattern, using a portion of the second liner layer formed in the cell region as an etching stop layer, the portion of the second liner layer remaining in the cell region after etching the second liner layer in the peripheral circuit region; and
exposing the first column lines by etching the remaining portion of the second liner layer and the first additional protective layers.

8. The method of claim 5, further comprising:
forming a first liner layer that covers the first memory lines and the first row lines.

9. The method of claim 5, wherein the first additional protective layers include a nitride.

10. The method of claim 1, further comprising:
forming a peripheral circuit on the substrate; and
forming an interconnection structure connected to the first contact via and the peripheral circuit.

11. The method of claim 10, wherein the first contact via is electrically connected to the peripheral circuit.

12. The method of claim 1, further comprising:
forming second column lines that extend in the second direction on the first column lines;
forming second row lines that extend in the first direction; and
forming second memory cells respectively positioned between the second column lines and the second row lines, in the cell region and the peripheral circuit region.

13. The method of claim 12, further comprising:
forming second memory lines that extend in the second direction;
forming second additional protective layers on the second memory lines; and
etching the second memory lines to form the second memory cells, using the second additional protective layers as an etching barrier.

14. The method of claim 13, further comprising:
forming a third liner layer that covers the second memory lines and the second column lines; and
forming a fourth liner layer that covers the second additional protective layers, the second row lines, and the second memory cells.

15. The method of claim 14, further comprising:
forming a third protective layer on the fourth liner layer;
forming a second trench by etching the third protective layer, the fourth liner layer, the second additional protective layers, the second row lines, the second memory cells, and the second column lines formed in the peripheral circuit region;
forming a second interlayer insulating layer in the second trench; and
forming a second contact via that extends through the second interlayer insulating layer and connected to the first contact via.

16. The method of claim 15, wherein a remaining portion of the third protective layer in the cell region after etching the third protective layer in the peripheral circuit region is a third protective pattern, the method further comprising:
forming a fourth protective layer along the third protective pattern and in the second trench to extend from the cell region to the peripheral circuit region.

17. The method of claim 15, wherein the third protective layer contacts the fourth liner layer.
